(19) United States
(12) Patent Application Publication
(10) Pub. No.: US 2006/0221701 A1
(43) Pub. Date: Oct. 5, 2006

(54) Time division driven display and method for driving same

(75) Inventor: Wein-Town Sun, Taoyuan County (TW)

Correspondence Address: BACON & THOMAS, PLLC, 625 SLATERS LANE, FOURTH FLOOR, ALEXANDRIA, VA, 22314, US

(73) Assignee: AU OPTRONICS CORP., Hsin-Chu (TW)

(21) Appl. No.: 11/188,842

(22) Filed: Jul. 26, 2005

(30) Foreign Application Priority Data
Apr. 1, 2005 (TW) 94110624

(51) Int. Cl. G11C 11/34

(52) U.S. Cl. 365/185.22

(57) ABSTRACT

A time division driven display and a method for driving the same. The display includes a panel having data lines, a source driver having output pins, a precharge controller and a demultiplexer. The precharge controller electrically connected to these data lines selects one from these data lines to precharge. The demultiplexer coupled to the output pins and these data lines couples the corresponding output pin to the selected data line for the source driver to drive the selected data line after the selected data line is precharged.

This application claims the benefit of Taiwan application Serial No. 94110624, filed Apr. 1, 2005, the subject matter of which is incorporated herein by reference.

### BACKGROUND OF THE INVENTION

1. Field of the Invention

The invention relates in general to a display and a method for driving the same, and more particularly to a time division driven display and a method for driving the same.

2. Description of the Related Art

A source driver of a typical LCD (Liquid Crystal Display) has a plurality of pins connected, one by one, to a plurality of data lines of a panel. As the resolution of the LCD is getting higher and higher, the number of pins of the source driver is getting more and more such that the area occupied by the pins is getting larger and larger. In order to reduce the number of pins in the source driver, a time division method may be adopted to drive the LCD.

FIG. 1A is a schematic illustration showing a conventional time division driven LCD. Referring to FIG. 1A, a LCD 100 includes a source driver 110, a gate driver 112, a demultiplexer 120 and a panel 130. The demultiplexer 120 includes selection control lines CS1 to CS6 and a plurality of driving switches SW. The panel has a plurality of pixels P. The source driver 110 has multiple output pins DO1 to DOn. Taking DO1 as an example, it is selectively electrically connected to one of data lines DL1 to DL6 on the panel 130 through the demultiplexer 120. Thus, the number of the output pins of the source driver 110 may be effectively reduced and the chip area thereof may be reduced accordingly.

FIG. 1B shows a drive timing chart for the LCD of FIG. 1A. When a gate line SL1 is enabled, the period in which the gate line SL1 is maintained at the high level is the charging period, which is divided into a plurality of sub-charging periods. In this example, six sub-charging periods T1 to T6 are defined. First, the signal selecting line CS1 is enabled within the sub-charging period T1 to turn on the driving switch SW1 to drive the data line DL1. Next, the signal selecting line CS2 is enabled within the sub-charging period T2 to turn on the driving switch SW2 to drive the data line DL2. Similarly, the signal selecting lines CS3 to CS6 are enabled within the sub-charging periods T3 to T6 to turn on the driving switches SW3 to SW6 to drive the data lines DL3 to DL6, respectively.

However, when the time division driving method is adopted, the charging period assigned to each data line becomes shorter, as shown in FIG. 1B, wherein the charging period of each data line is only one-sixth of the enable period of the gate line SL. In addition, the RC value on each gate line causes the gate delay such that each data line does not have a sufficient charging period and the frame displaying quality is thus affected.

### SUMMARY OF THE INVENTION

It is therefore an object of the invention to provide a time division driven display and a method for driving the same to improve the frame displaying quality.

The invention achieves the above-identified object by providing a time division driven display and a method for driving the same. The display includes a panel having a plurality of data lines, a source driver having at least one output pin, a precharge controller, and a demultiplexer. The precharge controller electrically connected to these data lines selects one of these data lines to precharge. The demultiplexer coupled to the output pin and these data lines connects the selected data line to the output pin after the selected data line is precharged such that the source driver drives the selected data line.

The invention also achieves the above-identified object by providing a time division driving method for driving n data lines, including a data line (1) to a data line (n), of a display within a charging period, wherein n is a positive integer. The charging period is divided into a plurality of sub-charging periods including a sub-charging period (0) to a sub-charging period (n). First, a data line (i) is selected from these data lines, wherein i is a positive integer smaller than or equal to n. Then, at least one sub-charging period is selected from these sub-charging periods (0) to (i−1). Next, the data line (i) is precharged within the selected sub-charging period. Then, the data line (i) is driven within the sub-charging period (i). The above-mentioned steps are repeated until these data lines have been driven.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a schematic illustration showing a conventional time division driven LCD.

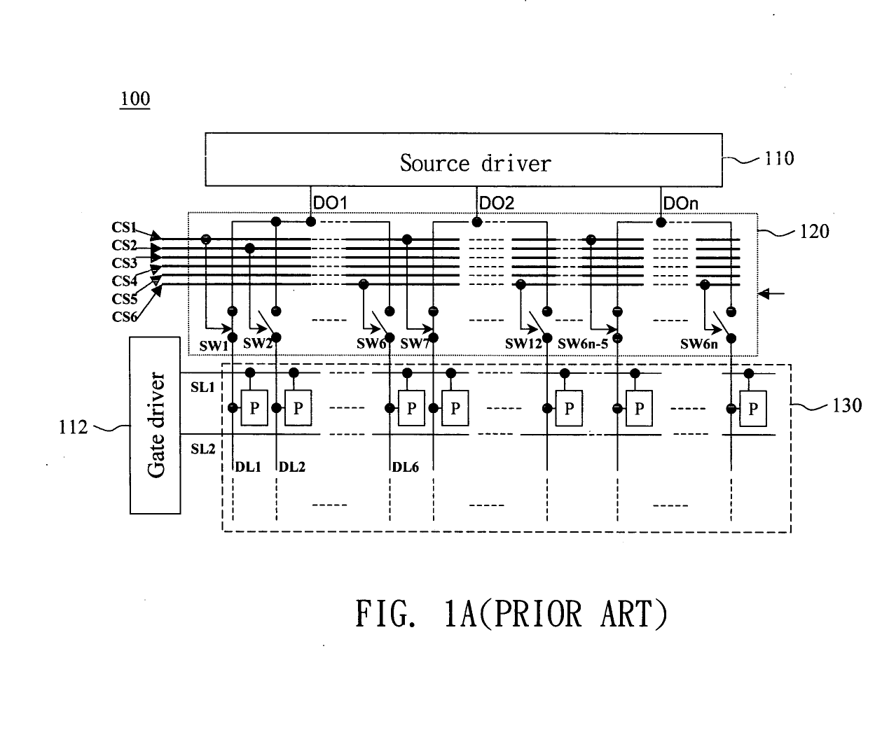

FIG. 1B shows a drive timing chart for the LCD of FIG. 1A.

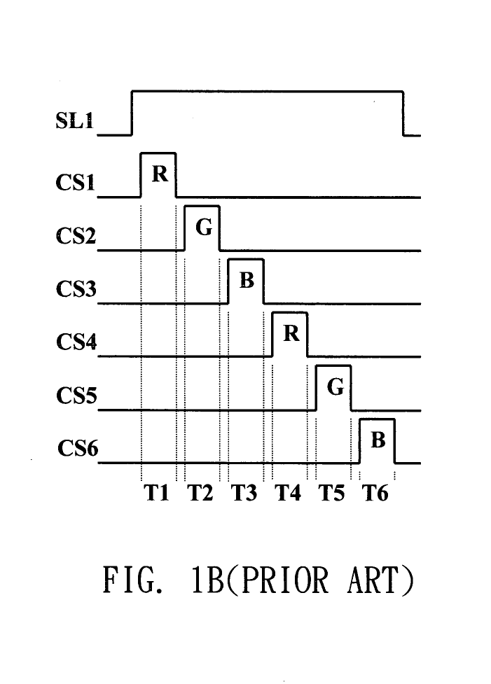

FIG. 2A is a schematic illustration showing a time division driven LCD according to a first embodiment of the invention.

FIG. 2B shows a first drive timing chart for the LCD of FIG. 2A.

FIG. 2C shows a second drive timing chart for the LCD of FIG. 2A.

FIG. 2D shows a third drive timing chart for the LCD of FIG. 2A.

FIG. 2E shows a fourth drive timing chart for the LCD of FIG. 2A.

FIG. 3A is a schematic illustration showing a time division driven LCD according to a second embodiment of the invention.

FIG. 3B shows a drive timing chart for the LCD of FIG. 3A.

FIG. 4A is a schematic illustration showing a time division driven LCD according to a third embodiment of the invention.

FIG. 4B shows a drive timing chart for the LCD of FIG. 4A.

FIG. 5A is a schematic illustration showing a time division driven LCD according to a fourth embodiment of the invention.

FIG. 5B shows a drive timing chart for the LCD of FIG. 5A.

FIG. 6A is a schematic illustration showing a time division driven LCD according to a fifth embodiment of the invention.

FIG. 6B shows a drive timing chart for the LCD of FIG. 6A.

### DETAILED DESCRIPTION OF THE INVENTION

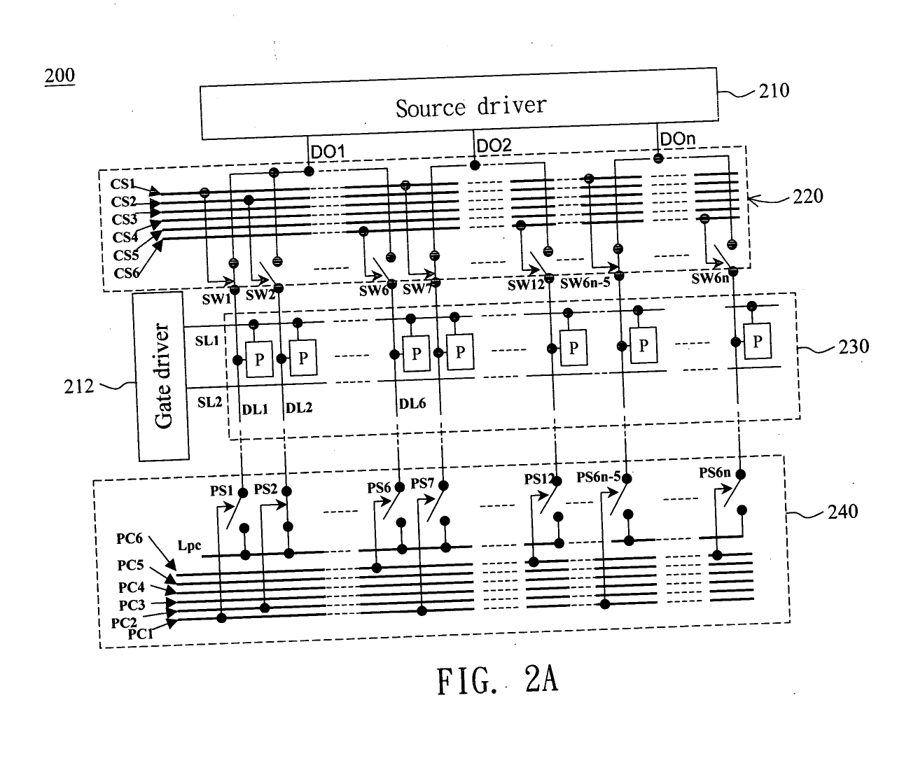

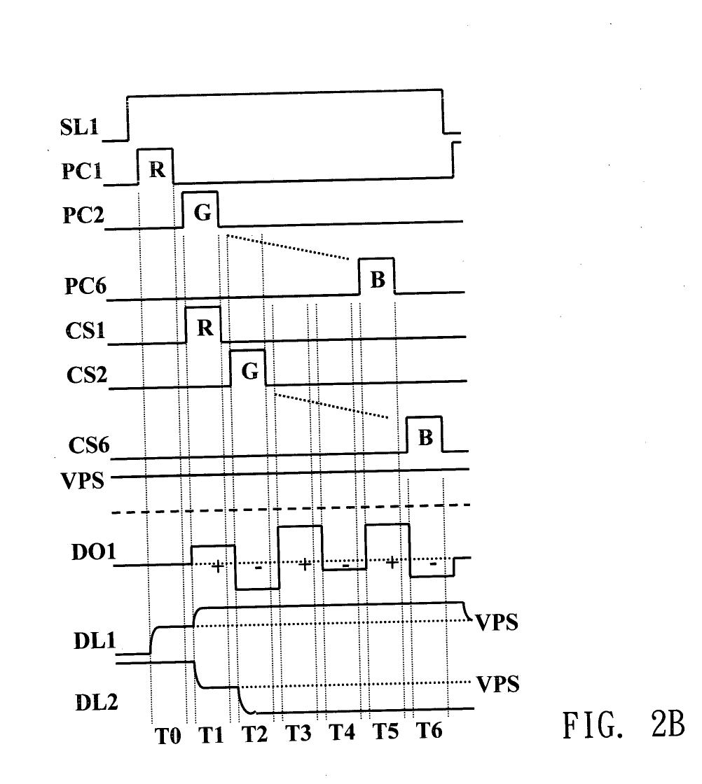

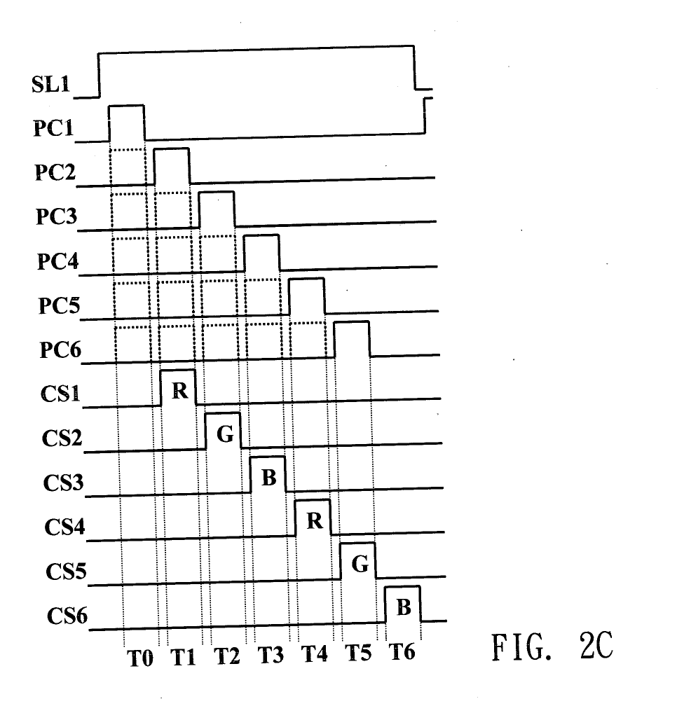

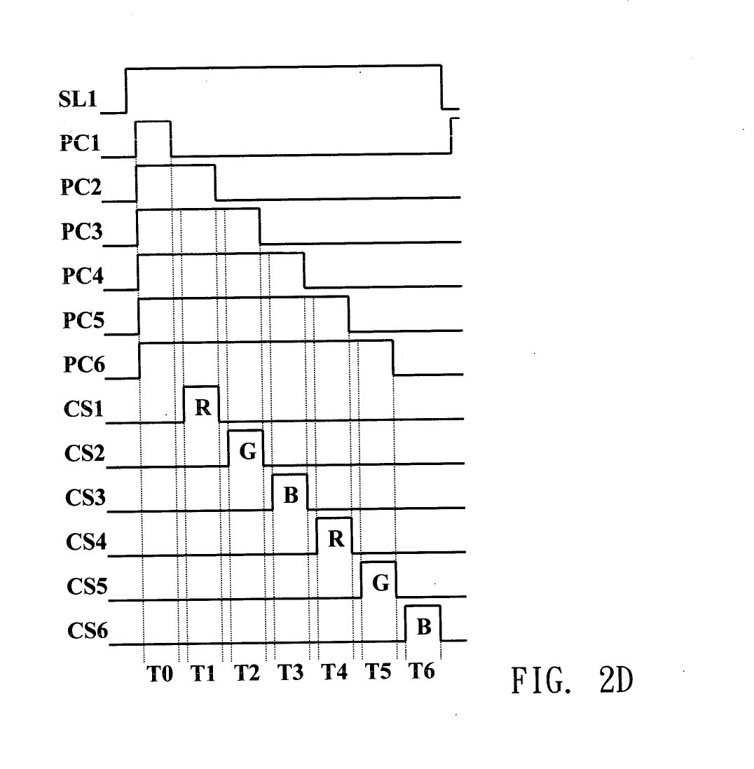

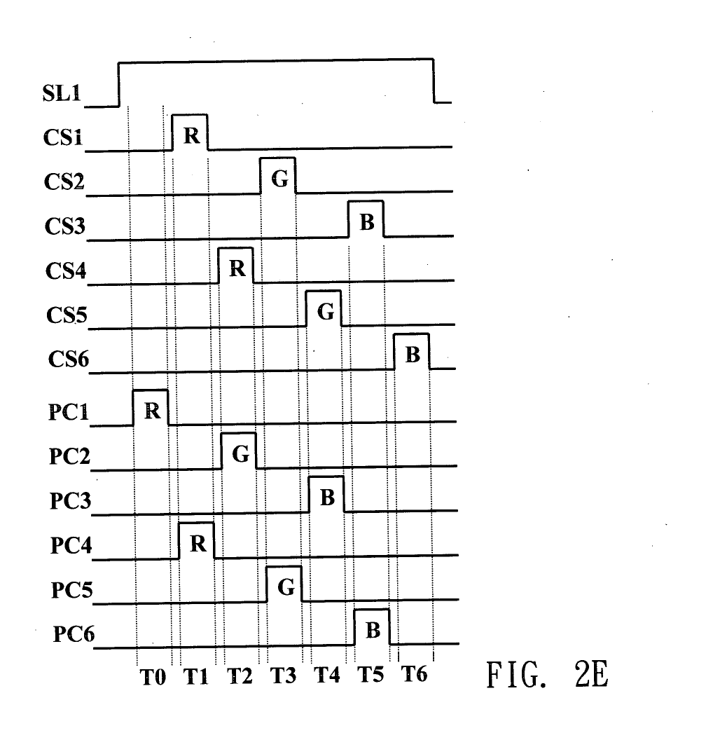

FIG. 2A is a schematic illustration showing a time division driven LCD according to a first embodiment of the invention. Referring to FIG. 2, the LCD 200 includes a source driver 210, a gate driver 212, a demultiplexer 220, a panel 230 and a precharge controller 240. The source driver 210 includes a plurality of output pins DO1 to DOn selectively electrically connected to one of data lines DL on the panel 230 through the demultiplexer 220, respectively. For example, DL1 corresponds to a red (R) pixel P, DL2 corresponds to a green (G) pixel P, and DL3 corresponds to a blue (B) pixel P. The precharge controller 240 electrically connected to these data lines DL selects one of the data lines DL to precharge. After the precharge, the demultiplexer 220 electrically connects the selected data line DL to the corresponding output pin such that the selected data line DL is driven by the source driver 210.

The demultiplexer 220 includes selection control lines CS1 to CS6 and a plurality sets of driving switches SW. Each set of the driving switches SW, such as the first set of driving switches SW1 to SW6, is respectively controlled by the selection control lines CS1 to CS6 to electrically connect the output pin to one of the data lines DL selectively.

The precharge controller 240 includes a precharge signal line Lpc, precharge control lines PC1 to PC6 and a plurality sets of precharge switches PS. Each precharge switch PS is controlled by one of the precharge control lines PC1 to PC6. For example, the precharge control lines PC1 to PC6 control the first set of precharge switches PS1 to PS6 to selectively electrically connect the precharge signal line Lpc to one of the data lines to precharge. The voltage level of the precharge signal line Lpc is the precharge voltage VPS.

That is, one output pin (e.g., DO1) of the source driver 210 corresponds to one set of driving switches SW1-SW6, one set of data lines DL1 to DL6 and one set of precharge switches PS1 to PS6.

FIG. 2B shows a first drive timing chart for the LCD of FIG. 2A. When the gate line SL1 is enabled, the gate line SL1 is kept at the high level for a charging period, which is divided into a plurality of sub-charging periods. In this embodiment, the charging period is divided into seven sub-charging periods T0 to T6. First, the precharge control line PCd is enabled to turn on the precharge switch PS1 so as to electrically connect the data line DL1 to the precharge signal line Lpc to precharge the data line DL1 within the sub-charging period T0. So, the level of the data line DL1 is risen to the precharge voltage VPS. Next, the selection signal CS1 is enabled to turn on the driving switch SW1 so as to electrically connect the data line DL1 to the output pin DO1 and drive the data line DL1 within the sub-charging period T1. Thus, the level of the data line DL1 is changed accordingly. Because the data line DL1 only has to be converted from the precharge voltage VPS into the drive voltage outputted from the source driver 210, the increase of the level is smaller and the required charging period may be shortened.

Meanwhile, the precharge control line PC2 is enabled to precharge the data line DL2 within the sub-charging period T1. Then, the selection signal CS2 is enabled to make the output pin DO1 output the drive voltage to drive the data line DL2 within the sub-charging period T2. According to the above-mentioned steps, the data line DL is precharged with the precharge voltage VPS in advance before the data line DL is driven. So, the problem of the insufficient charging period may be solved.

FIG. 2C shows a second drive timing chart for the LCD of FIG. 2A, wherein the difference between the second and first drive timings resides in the precharge timing. In the first drive timing, the precharge timing ends in a sub-charging period before the drive timing. In the second drive timing, the precharge timing is not limited to a sub-charging period before the drive timing, and only the precharge operation has to be completed before the drive timing. For example, the selection control line CS2 is enabled to drive the data line DL2 within the sub-charging period T2, and the operation of precharging the data line DL2 may be performed within the sub-charging period T1 or T0. Similarly, the precharge data line DL6 is driven within the sub-charging period T6. So, the precharge operation may be performed in one time interval, which is optionally selected from the sub-charging periods T0 to T5.

FIG. 2D shows a third drive timing chart for the LCD of FIG. 2A, wherein the difference between the third and the first and second drive timings resides in the precharge time length. The precharge time length for the first and second drive timings equals one sub-charging period, while the precharge time length of the third drive timing may cross over several sub-charging periods. For example, the selection control line CS2 is enabled to drive the data line DL2 within the sub-charging period T2, and the operation of precharging the data line DL2 may be performed within the sub-charging periods T0 to T1. Similarly, the precharge data line DL6 is driven within the sub-charging period T6, so the data line DL6 is precharged within the sub-charging periods T0 to T5.

FIG. 2E shows a fourth drive timing chart for the LCD of FIG. 2A, wherein the difference between the fourth and first drive timings resides in the precharge order. The first drive timing drives the data lines according to the spatial order of the data lines, while the driving order of the fourth drive timing is determined according to the colors corresponding to the data lines. For example, the red data lines are driven first. That is, the data lines DL1 and DL4 are driven within the sub-charging periods T1 and T2, respectively, and PC1 and PC4 are enabled in advance within the sub-charging periods T0 and T1 before driving so that the data lines DL1 and DL4 are precharged. Next, the green data lines DL2 and DL5 are driven. Then the blue data lines DL3 and DL6 are driven.

The driving methods for precharging before the drive timing in FIGS. 2B to 2E may be modified easily by one of ordinary skill in the art under the teaching of the disclosed driving methods of this embodiment, and detailed descriptions thereof will be omitted.

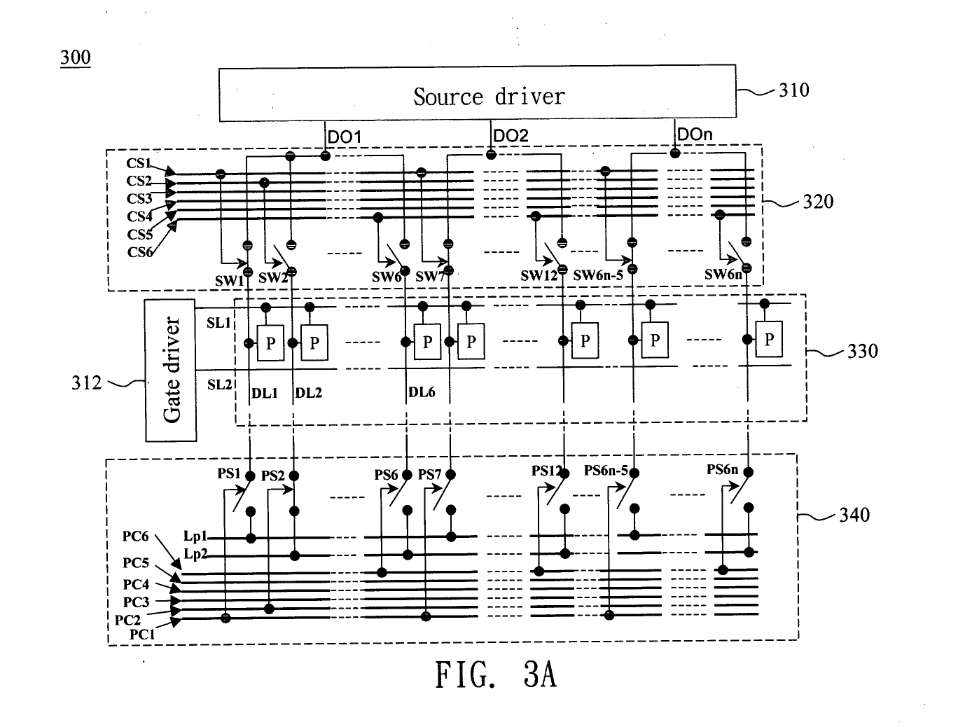

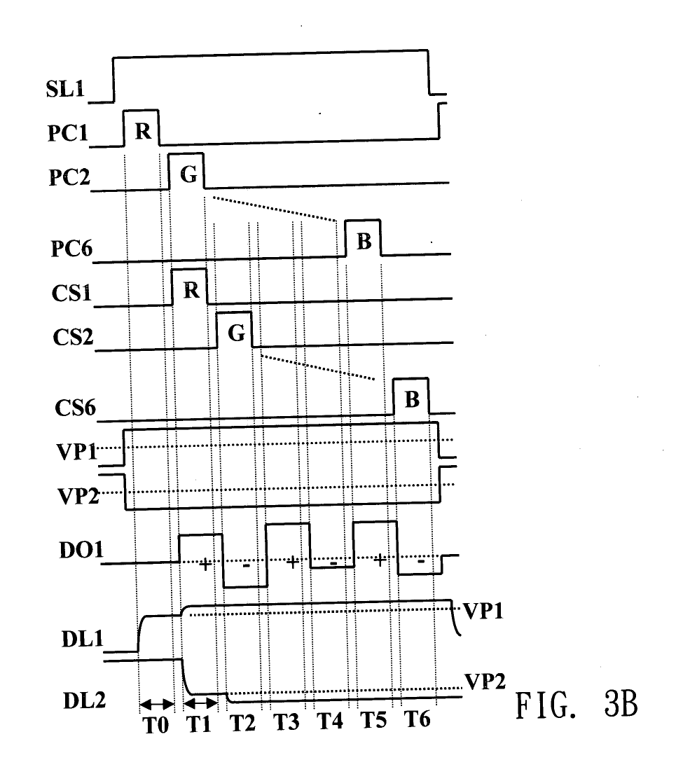

FIG. 3A is a schematic illustration showing a time division driven LCD according to a second embodiment of the invention. Referring to FIG. 3A, the LCD 300 includes a source driver 310, a gate driver 312, a demultiplexer 320, a panel 330 and a precharge controller 340. The demultiplexer 320 includes selection control lines CS1 to CS6 and a plurality of driving switches SW. The precharge controller 340 includes precharge signal lines Lp1 and Lp2, precharge control lines PC1 to PC6 and a plurality of precharge switch PS. The difference between the second embodiment and the first embodiment of FIG. 2A is that the number of precharge signal lines is two, the voltage level of the precharge signal line Lp1 is the positive precharge voltage VP1, and the voltage level of the precharge signal line Lp2 is the negative precharge voltage VP2. The precharge controller 340 may select and precharge the precharge signal line Lp1 or Lp2 according to a polarity converting signal.

FIG. 3B shows a drive timing chart for the LCD of FIG. 3A. When the data line DL1 is driven within the sub-charging period T1, the data line DL1 is precharged with the positive precharge voltage VP1 within the sub-charging period T0 because the drive voltage has the positive polarity. When the data line DL2 is driven within the sub-charging period T2, the data line DL2 is precharged with the negative precharge voltage-VP2 within the sub-charging period T1 because the drive voltage has the negative polarity.

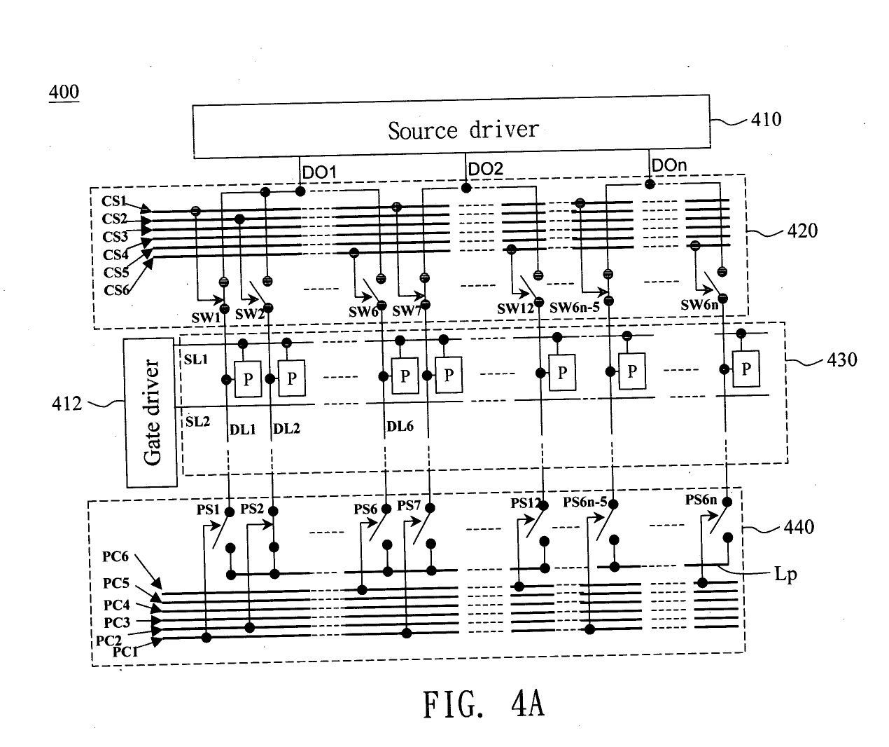

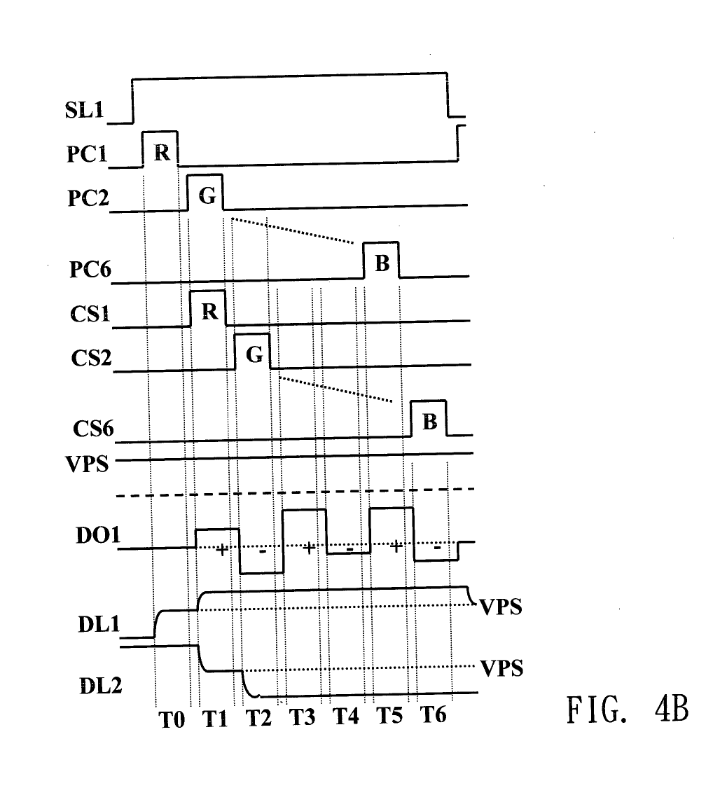

FIG. 4A is a schematic illustration showing a time division driven LCD according to a third embodiment of the invention. Referring to FIG. 4A, the LCD 400 includes a source driver 410, a gate driver 412, a demultiplexer 420, a panel 430 and a precharge controller 440. The demultiplexer 420 includes selection control lines CS1 to CS6 and a plurality of driving switches SW. The precharge controller 440 includes a precharge signal line Lp, precharge control lines PC1 to PC6 and a plurality of precharge switches PS. The difference between the third embodiment and the first embodiment is that the precharge voltage of the precharge signal line Lp of the precharge controller 440 does not have to be provided from the outside, and is obtained by coupling the terminals at a side of each of the precharge switches together. Because the precharge signal line Lp is very long, the voltage thereof approximates the common electrode voltage. The drive timing of the LCD 400, as shown in FIG. 4B, is the same as that of the first embodiment, so detailed descriptions thereof will be omitted.

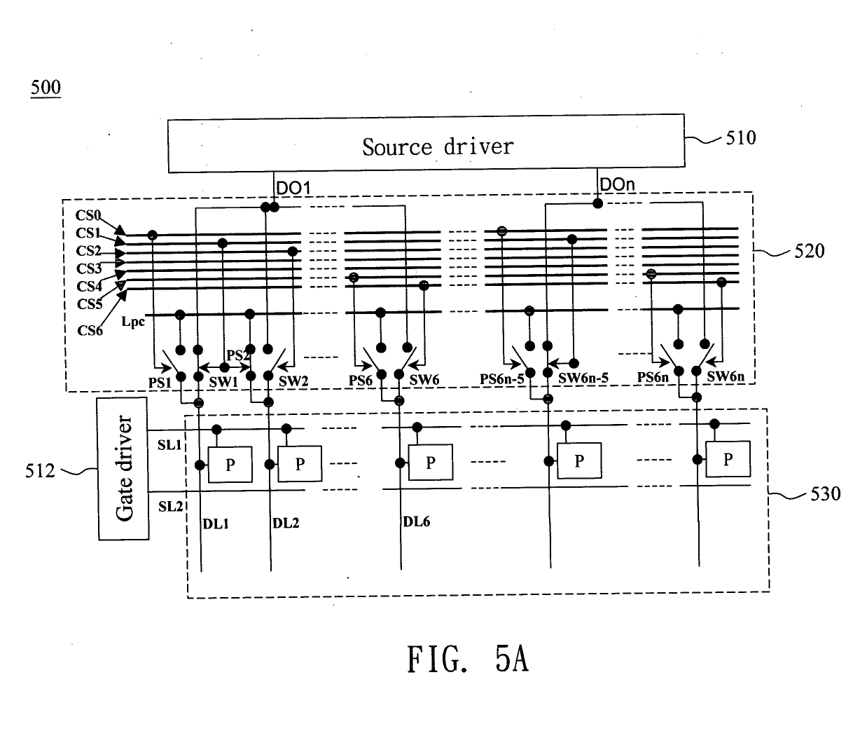

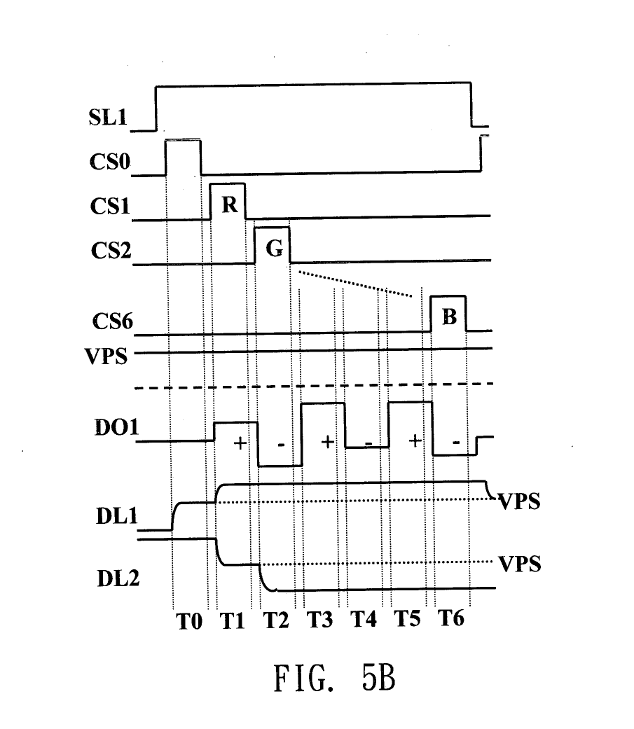

FIG. 5A is a schematic illustration showing a time division driven LCD according to a fourth embodiment of the invention. Referring to FIG. 5A, the LCD 500 includes a source driver 510, a gate driver 512, a demultiplexer/precharge controller 520 and a panel 530. The difference between the fourth embodiment and the first embodiment is that the demultiplexer and the precharge controller are combined into the demultiplexer/precharge controller 520. The demultiplexer/precharge controller 520 includes selection control lines CS1 to CS6, a plurality of driving switches SW, a precharge signal line Lpc and a plurality of precharge switches PS. One output pin (e.g., DO1) of the source driver 510 corresponds to a set of driving switches SW1 to SW6, a set of data lines DL1 to DL6, and a set of precharge switches PS1 to PS6. The selection control line CS1 simultaneously controls the precharge switch PS2 and the driving switch SW1, the selection control line CS2 simultaneously controls the, precharge switch PS3 and the driving switch SW2, and so on. The voltage level of the precharge signal line Lpc is the precharge voltage VPS.

FIG. 5B shows a drive timing chart for the LCD of FIG. 5A. Because the selection control line CS0 controls the precharge switch PS1, the enabled selection control line CS0 turns on the precharge switch PS1, and the data line DL1 is precharged with the precharge voltage VPS. When the selection control line CS1 is enabled, the driving switch SW1 and the precharge switch PS2 are turned on to drive the data line DL1 and to precharge the data line DL2. The conditions may be derived analogically such that all the data lines are precharged and then driven.

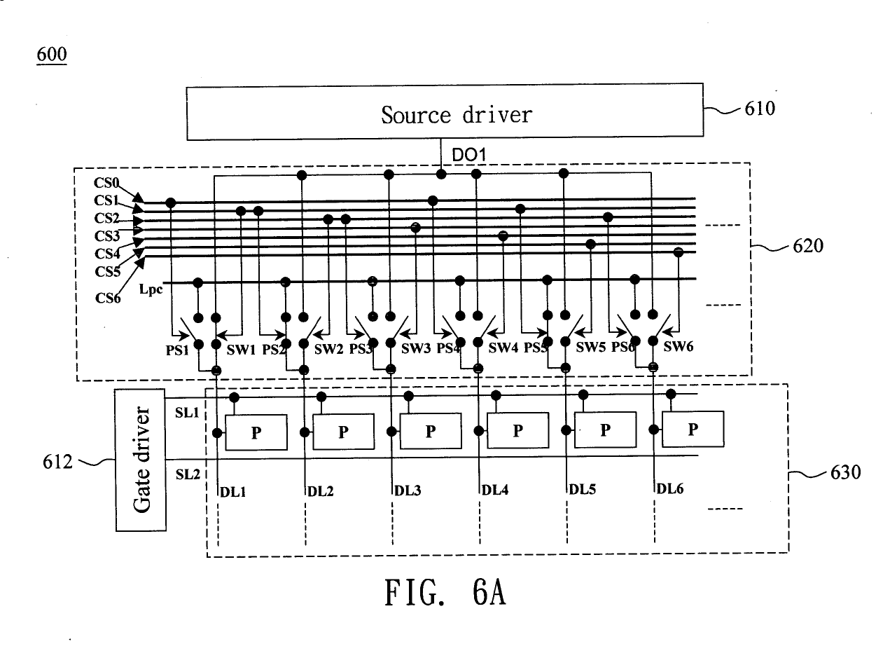

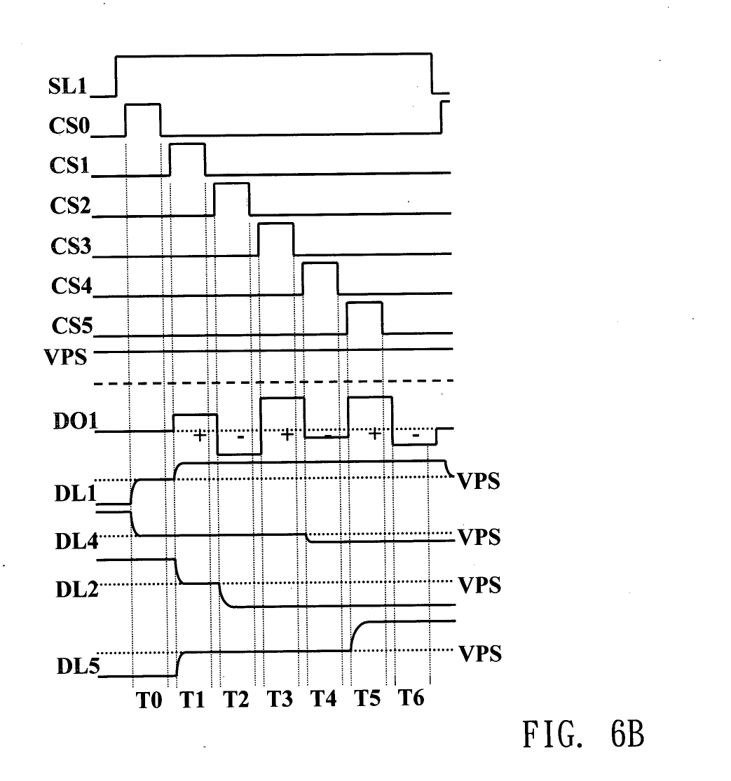

FIG. 6A is a schematic illustration showing a time division driven LCD according to a fifth embodiment of the invention. Referring to FIG. 6A, the LCD 600 includes a source driver 610, a gate driver 612, a demultiplexer/precharge controller 620 and a panel 630. The demultiplexer/precharge controller 620 includes selection control lines CS1 to CS6, a plurality of driving switches SW, a precharge signal line Lpc and a plurality of precharge switches PS. One output pin (e.g., DO1) of the source driver 610 corresponds to a set of driving switches SW1 to SW6, a set of data lines DL1 to DL6 and a set of precharge switches PS1 to PS6. The difference between the fifth embodiment and the fourth embodiment is that the selection control lines CS for controlling the precharge switches PS and the driving switches SW are different in the fifth embodiment. The selection control line CS0 controls the precharge switches PS1 and PS4. The selection control line CS1 controls the driving switch SW1 and the precharge switches PS2 and PS5. The selection control line CS2 controls the driving switch SW2 and the precharge switches PS3 and PS6. The selection control line CS3 controls the driving switch SW3. The selection control line CS4 controls the driving switch SW4. The selection control line CS5 controls the driving switch SW5. The selection control line CS6 controls the driving switch SW6.

FIG. 6B shows a drive timing chart for the LCD of FIG. 6A. First, the selection control line CS0 is enabled within the sub-charging period T0 such that the precharge switches PS1 and PS4 are turned on and the data lines DL1 and DL4 are precharged with the precharge voltage VPS. When the selection control line CS1 is enabled within the sub-charging period T1, the driving switch SW1 and the precharge switches PS2 and PS5 are turned on to drive the data line DL1 and precharge the data lines DL2 and DL5 simultaneously. The conditions may be derived analogically such that all the data lines are precharged and then driven.

The time division driven LCD according to the embodiments of the invention can precharge the data line with the precharge voltage before the data line is driven. So, the charging period for driving the data line may be shortened.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A time division driving method for driving n data lines, comprising a data line (1) to a data line (n), of a display within a charging period, wherein n is a positive integer, the charging period is divided into a plurality of sub-charging periods, comprising a sub-charging period (0) to a sub-charging period (n), the method comprising the steps of:
selecting the data line (i) from the data lines, wherein i is a positive integer smaller than or equal to n;
selecting at least one sub-charging period from the sub-charging periods (0) to (i−1);
precharging the data line (i) within the at least one selected sub-charging period;
driving the data line (i) within the sub-charging period (i); and
repeating the above-mentioned steps until the data lines have been driven.

2. The method according to claim 1, wherein the sub-charging period (i−1) is selected in the step of selecting the at least one sub-charging period.

3. The method according to claim 1, wherein the sub-charging periods from the sub-charging period (0) to the sub-charging period (i−1) are selected in the step of selecting the at least one sub-charging period.

4. The method according to claim 1, wherein the data lines are sequentially selected according to a spatial order of the data lines.

5. The method according to claim 1, wherein the data lines are selected according to corresponding colors thereof.

6. The method according to claim 1, wherein a precharge voltage for precharging the data line (i) is determined according to a polarity converting signal in the step of precharging the data line (i).

7. The method according to claim 1, wherein the data line (i) is precharged with a precharge voltage, which is substantially a common electrode voltage, in the step of precharging the data line (i).

8. A time division driven display, comprising:
a panel, which includes a plurality of data lines;
a source driver, which includes at least one output pin;
a precharge controller, which is electrically connected to the data lines, for selecting one of the data lines to precharge; and
a demultiplexer, which is coupled to the at least one output pin and the data lines, and connects the selected data line to the at least one output pin to enable the source driver to drive the selected data line after the selected data line is precharged.

9. The display according to claim 8, wherein the precharge controller comprises:
a precharge signal line;
a plurality of precharge control lines; and
a plurality of precharge switches respectively controlled by the precharge control lines to couple one of the data lines to the precharge signal line selectively.

10. The display according to claim 9, wherein the precharge signal line receives a precharge voltage.

11. The display according to claim 9, wherein first terminals of the precharge switches are respectively coupled to the data lines, and second terminals of the precharge switches are commonly coupled to the precharge signal line.

12. The display according to claim 8, wherein the precharge controller comprises:
a first precharge signal line and a second precharge signal line;
a plurality of precharge control lines; and
a plurality of precharge switches respectively controlled by the precharge control lines to couple one of the data lines to the first precharge signal line or the second precharge signal line according to a polarity converting signals selectively.

13. The display according to claim 8, wherein the demultiplexer comprises:
a plurality of selection control lines; and
a plurality of driving switches respectively controlled by the selection control lines to couple one of the data lines to the at least one output pin selectively.

14. The display according to claim 13, wherein the precharge controller comprises:
a precharge signal line; and
a plurality of precharge switches respectively controlled by one of the selection control lines.

15. The display according to claim 14, wherein:
the i-th selection control line controls the i-th driving switch and the (i+1)-th precharge switch;
the i-th driving switch selectively connects the at least one output pin to the i-th data line;
the (i+1)-th precharge switch selectively connects the precharge signal line to the (i+1)-th data line; and
i is a positive integer smaller than or equal to the number of the data lines.

16. The display according to claim 14, wherein:
the i-th selection control line controls the i-th driving switch, the (i+1)-th precharge switch and the (i+k)-th precharge switch, wherein k is a positive integer greater than 1;
the i-th driving switch selectively connects the at least one output pin to the i-th data line;
the (i+1)-th precharge switch selectively connects the precharge signal line to the (i+1)-th data line;
the (i+k)-th precharge switch selectively connects the precharge signal line to the (i+k)-th data line; and
i is a positive integer smaller than or equal to the number of the data lines, and (i+k) is smaller than or equal to the number of the data lines.
